(19) United States
(12) Patent Application Publication
(10) Pub. No.: US 2025/0006607 A1
(43) Pub. Date: Jan. 2, 2025

(54) SEMICONDUCTOR PACKAGE WITH RETREATING METAL LAYERS

(71) Applicant: TEXAS INSTRUMENTS INCORPORATED, Dallas, TX (US)

(72) Inventors: John Carlo C. MOLINA, Limay (PH); Nicole M. YABUUCHI, Angeles City (PH); Ruby Ann M. CAMENFORTE, Pampanga (PH)

(21) Appl. No.: 18/343,204

(22) Filed: Jun. 28, 2023

(51) Int. Cl. H01L 23/498; H01L 23/00; H01L 23/31

(52) U.S. Cl. CPC H01L 23/49822; H01L 23/3107; H01L 23/49838; H01L 23/49894; H01L 24/16; H01L 24/81; H01L 24/96; H01L 24/97; H01L 21/022; H01L 21/565; H01L 21/76877; H01L 21/784; H01L 2224/16238; H01L 2224/81191; H01L 2224/96; H01L 2224/97; H01L 2924/35121

(57) ABSTRACT

A package comprises a die having a device side including circuitry. The package also comprises a substrate facing and coupled to the device side. The substrate includes first and second metal layers, the first metal layer positioned closer to the device side than the second metal layer and coupled to the second metal layer by way of a via. The substrate includes a dielectric contacting part of the first and second metal layers and the via. The package comprises a mold compound covering the semiconductor die and the substrate. The package includes a lateral surface perpendicular to the first and second metal layers of the substrate. The mold compound, the dielectric, and the second metal layer are exposed to the lateral surface, a segment of the dielectric positioned between the first metal layer and the lateral surface, the segment of the dielectric contacting the mold compound at the lateral surface.

### BACKGROUND

Semiconductor chips are often housed inside packages that protect the chips from deleterious environmental influences, such as heat, moisture, and debris. A packaged chip generally communicates with electronic devices outside the package via conductive members (e.g., leads) that are exposed to surfaces of the package. Some packages include substrates on which the semiconductor die is positioned. The substrate may include multiple metal layers, or traces, that carry electrical signals or power.

### SUMMARY

In examples, a package comprises a die having a device side including circuitry. The package also comprises a substrate facing and coupled to the device side. The substrate includes first and second metal layers, the first metal layer positioned closer to the device side than the second metal layer and coupled to the second metal layer by way of a via. The substrate includes a dielectric contacting part of the first and second metal layers and the via. The package comprises a mold compound covering the semiconductor die and the substrate. The package includes a lateral surface perpendicular to the first and second metal layers of the substrate. The mold compound, the dielectric, and the second metal layer are exposed to the lateral surface, a segment of the dielectric positioned between the first metal layer and the lateral surface, the segment of the dielectric contacting the mold compound at the lateral surface.

In examples, a method for manufacturing a semiconductor package comprises plating a first metal layer; plating a second metal layer, a lateral end of the second metal layer displaced from a saw street closest to the lateral end by a distance of at least 100 microns; laminating a dielectric material contacting the first and second metal layers; coupling a device side of a semiconductor die to the second metal layer, the device side having circuitry formed therein; covering the semiconductor die with a mold compound, the mold compound contacting the dielectric material at the saw street; and sawing along the saw street so as to saw through the mold compound, the dielectric material, and the first metal layer, but not through the second metal layer.

### BRIEF DESCRIPTION OF THE DRAWINGS

FIG. 1 is a block diagram of an electronic device containing a semiconductor package with retreating metal layers, in accordance with various examples.

FIG. 2A is a cross-sectional view of a semiconductor package with retreating metal layers, in accordance with various examples.

FIG. 2B is a top-down view of a semiconductor package with retreating metal layers, in accordance with various examples.

FIG. 2C is a perspective view of a semiconductor package with retreating metal layers, in accordance with various examples.

FIG. 2D is a profile view of a semiconductor package with retreating metal layers, in accordance with various examples.

FIG. 2E is a bottom-up view of a semiconductor package with retreating metal layers, in accordance with various examples.

FIG. 3 is a flow diagram of a method for manufacturing a semiconductor package with retreating metal layers, in accordance with various examples.

FIGS. 4A-4P are a process flow for manufacturing a semiconductor package with retreating metal layers, in accordance with various examples.

### DETAILED DESCRIPTION

Many semiconductor packages include a semiconductor die and conductive terminals exposed to an exterior surface of the package. The semiconductor die exchanges electrical signals with the conductive terminals so the die can communicate with components outside of the package, such as other chips that may be co-mounted on a printed circuit board (PCB) with the package. To provide electrical pathways between the semiconductor die and the conductive terminals, various structures may be useful, such as bond wires, redistribution layers, etc.

Some packages contain a substrate that has multiple metal layers (also known as a metal stack) to provide the aforementioned electrical pathway between the semiconductor die and the conductive terminals. In such packages, electrical currents may flow from the conductive terminal, through the metal stack in the substrate, and to the semiconductor die, or from the semiconductor die, through the metal stack in the substrate, and to the conductive terminal. Such substrates may contain a network of metal layers that are covered by an insulative film, such as AJINOMOTO® build-up film (ABF). These substrates are manufactured by forming a first metal layer, covering the first metal layer with ABF, then forming a second metal layer and covering the second metal layer with ABF, and so on, until a fully customized substrate is formed. Such substrates provide significant design flexibility.

Generally, during manufacture, the substrates are formed in sets or arrays, and then sets or arrays of semiconductor dies are coupled to the sets or arrays of substrates, with one semiconductor die coupled to each substrate. A mold compound is applied to cover the semiconductor dies and the substrates, thus forming a mold compound bar that contains within it the array of semiconductor dies and substrates. The mold compound bar has saw streets or other markings that indicate where singulation should occur to separate the substrates and dies from each other to form individual semiconductor packages.

In some cases, the metal layers in the substrates are formed in vertical alignment with the saw streets. Stated another way, when a sawing process is performed on the mold compound bar, the sawing tool (e.g., mechanical saw or laser) cuts through the metal layers of the substrate as the sawing tool cuts through the mold compound bar. This act of cutting through the metal layers, particularly when those metal layers are positioned in vertical proximity to the interface between the mold compound and the substrate film, imparts substantial stress to the mold compound bar. This stress is significant enough to cause irreparable damage to the mold compound bar, especially at the mold compound-substrate interface. For example, significant delamination may occur. These deleterious effects reduce yield and present a meaningful technical problem.

This disclosure describes various examples of a semiconductor package with retreating metal layers. In examples, the semiconductor package includes a semiconductor die having a device side including circuitry formed therein. The package includes a substrate facing and coupled to the device side. The substrate includes first and second metal layers, the first metal layer positioned closer to the device side than the second metal layer and coupled to the second metal layer by way of a via. The substrate also includes a dielectric contacting at least part of the first and second metal layers and the via. The package further includes a mold compound covering the semiconductor die and the substrate. The package includes a lateral surface approximately perpendicular to the first and second metal layers of the substrate. The mold compound, the dielectric, and the second metal layer are exposed to the lateral surface. A segment of the dielectric is positioned between the first metal layer and the lateral surface. Accordingly, the first metal layer is said to be a retreating metal layer because it is set back from the lateral surface. Because the first metal layer does not reach the lateral surface, during manufacture of the package, the sawing tool does not cut through the first metal layer, and thus the deleterious stresses described above are mitigated. The segment of the dielectric contacts the mold compound at the lateral surface. This disclosure thus provides a technical solution to the technical problem described above.

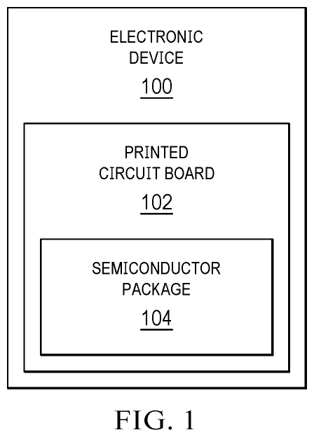

FIG. 1 is a block diagram of an electronic device 100 containing a semiconductor package with retreating metal layers, in accordance with various examples. More specifically, the electronic device 100 includes a printed circuit board (PCB) 102 on which a semiconductor package 104, such as a semiconductor package with retreating metal layers, is mounted. The electronic device 100 may be any suitable type of device, such as a computer (e.g., laptop, desktop, notebook, tablet, smartphone), a consumer electronic device (e.g., television, audio devices, security systems), appliances, automobiles, aircraft, spacecraft, etc., although the scope of this disclosure is not limited as such, and the semiconductor package 104 may be useful in any of a variety of contexts not expressly mentioned herein.

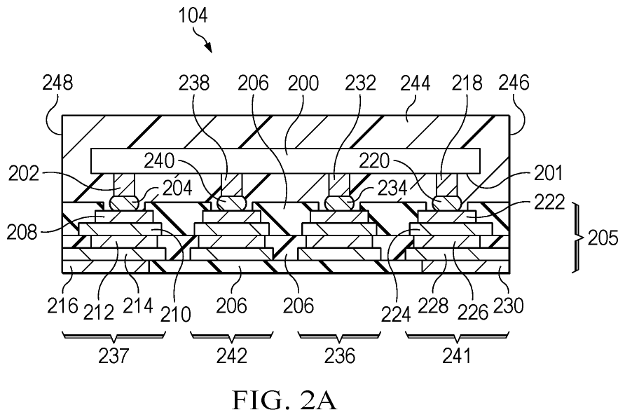

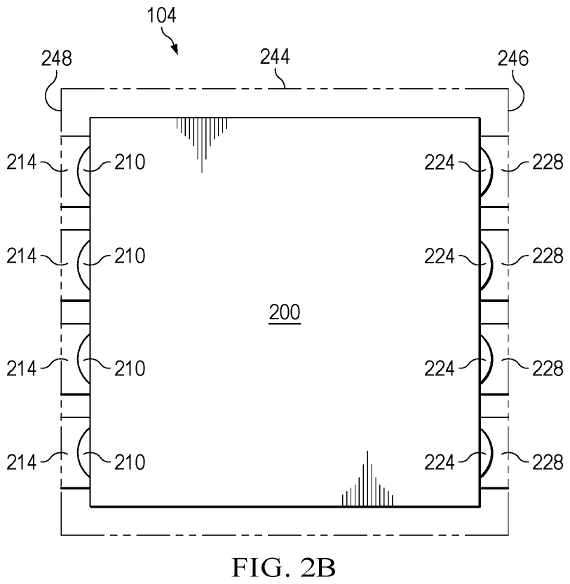

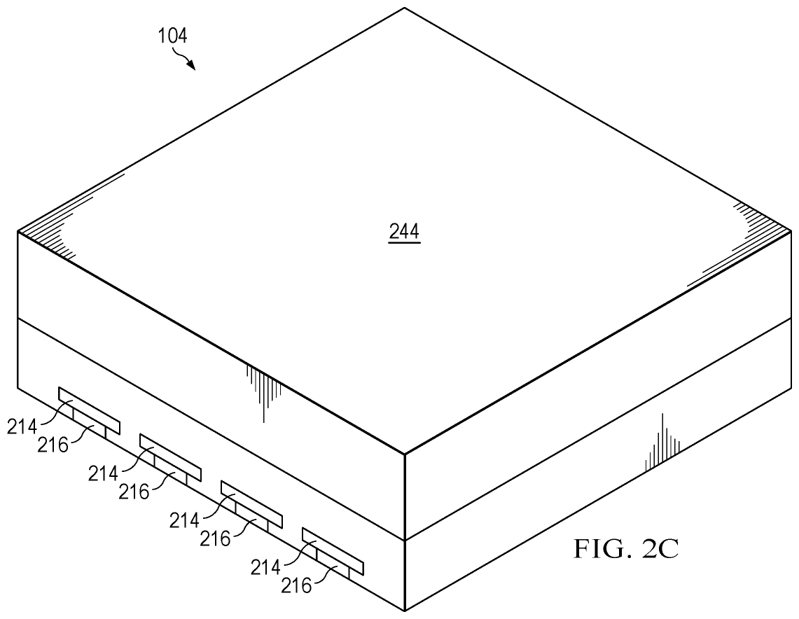

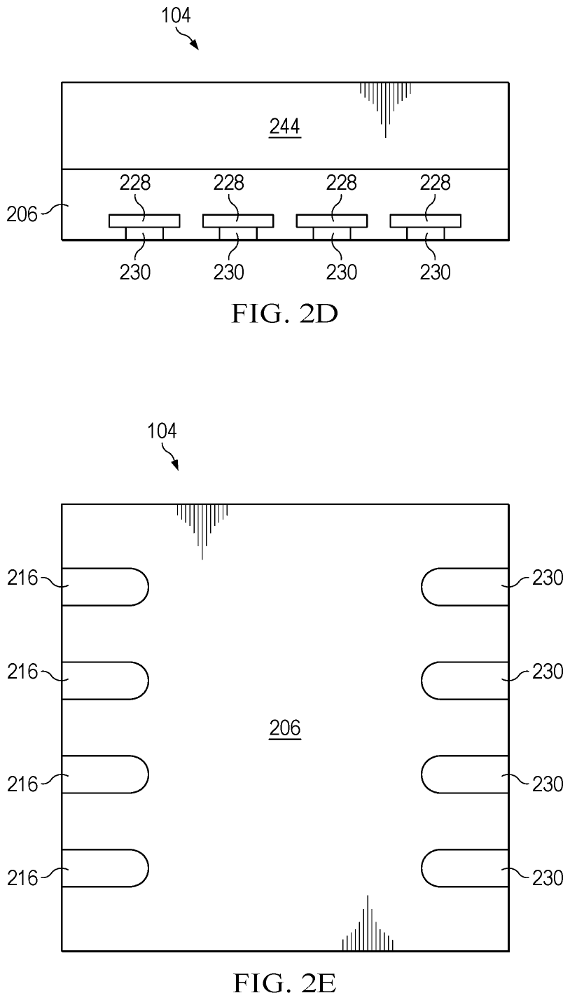

FIG. 2A is a cross-sectional view of the semiconductor package 104 with retreating metal layers, in accordance with various examples. The semiconductor package 104 comprises a semiconductor die 200 including a device side 201 having circuitry formed therein, and a non-device side opposing the device side 201. The semiconductor package 104 further comprises conductive members 202, 218, 232, and 238 coupled to the device side 201. In examples, the conductive members 202, 218, 232, and 238 are copper members (e.g., copper pillars), although any conductive material in any suitable shape may be useful. The semiconductor package 104 includes solder bumps 204, 220, 234, 240 coupled to the conductive members 202, 218, 232, 238, respectively, to provide electrical pathways between the conductive members 202, 218, 232, 238 and metal layers in a substrate of the semiconductor package 104, as now described.

The semiconductor package 104 includes a substrate 205. The substrate 205 comprises dielectric material 206 and a network of metal layers designed to implement application-specific electrical pathways (e.g., electrical pathways between solder bumps 204, 220, 234, 240 and metal layers exposed to a surface of the semiconductor package 104 to facilitate communications with devices outside of the semiconductor package 104). The dielectric material 206 may comprise, for example, AJINOMOTO® build-up film (ABF), although other films and materials with similar properties are contemplated. The network of metal layers includes internal metal stacks 236 and 242, which are positioned away from lateral surfaces of the semiconductor package 104. The network of metal layers also includes external metal stacks 237 and 241, which are positioned adjacent to the lateral surfaces of the semiconductor package 104. The metal layers in the metal stacks 236, 237, 241, and 242 may comprise any suitable metal, such as the plateable metals aluminum and copper.

The substrate 205 differs from a PCB because the substrate 205 is within the semiconductor package 104, whereas the PCB (e.g., PCB 102) is outside the semiconductor package 104. The substrate 205 includes multiple metal layers that are covered by a solid, tangible dielectric material 206, whereas the PCB may contain multiple layers of printed circuit board that may not be separated by a dielectric material other than air.

The metal stack 237 includes metal layers 208, 210, 212, 214, and 216. Some of the metal layers 208, 210, 212, 214, and 216 may comprise metal traces and others of these metal layers may comprise metal vias, but this distinction between metal traces and vias is minimally relevant in this disclosure, and they are collectively referred to herein as “metal layers.” The metal stack 241 includes metal layers 222, 224, 226, 228, and 230. Some of the metal layers 222, 224, 226, 228, and 230 may comprise metal traces and others of these metal layers may comprise metal vias, but this distinction between metal traces and vias is minimally relevant in this disclosure, and they are collectively referred to herein as “metal layers.” Solder bumps 204 and 220 couple to metal layers 208 and 222, respectively. Solder bumps 234 and 240 couple to the top metal layers in metal stacks 236 and 242, respectively. The semiconductor package 104 may be coupled to a PCB, such as PCB 102 (FIG. 1), by soldering the metal layers 216 and 230 to the PCB 102. A mold compound 244 covers the various structures of FIG. 2A.

As FIG. 2A shows, at least some of the metal layers in the metal stacks adjacent to lateral surfaces of the semiconductor package 104 are retreated from the lateral surfaces. For example, the metal layer 222, 224 and 226 could have been formed to interface with a lateral surface 246, but instead, the metal layers 222, 224 and 226 are deliberately formed to be offset, or retreated, from the lateral surface 246 by a predetermined distance, with the offset being filled by dielectric material 206. This retreat of the metal layers 222, 224 and 226 from the lateral surface 246 is beneficial because the amount of metal sawn during the singulation process is significantly reduced. Thus, the deleterious stresses (and related consequences, such as delamination) described above that would normally be introduced by the process of sawing through metal are mitigated. The retreat of a metal layer 224 from a closest lateral surface must be at least 100 microns (at least 125 microns in the case of metal layers 222, 226) to achieve this benefit. More generally, the metal layer 224 must be at least 100 microns (at least 125 microns in the case of metal layers 222, 226) away from every lateral surface of the semiconductor package 104 to achieve the benefit. In the case that a metal layer 224 is adjacent two lateral surfaces, such as when the metal layer is near a corner of the semiconductor package 104, the metal layer must be retreated from both lateral surfaces by at least 100 microns (at least 125 microns in the case of metal layers 222, 226) to achieve the benefits described above. These retreats of the metal layers from their respective lateral surfaces are implemented during manufacture of the semiconductor package 104, prior to the singulation (i.e., sawing) process. Similar to the retreat of the metal layers 222, 224 and 226, the retreat of the metal layers 208, 210, and 212 from a closest lateral surface (such as lateral surface 248) is beneficial for similar reasons, and the retreat of the metal layer 210 from the closest lateral surface (e.g., lateral surface 248) is at least 100 microns (at least 125 microns in the case of metal layers 208, 212) to achieve the benefits described herein, with the area between these metal layers and the lateral surface 248 being filled with dielectric material. In examples, the various metal layers lie in horizontal planes that are perpendicular to the lateral surfaces 246 and 248. In examples, the mold compound 244 contacts the dielectric material 206 at the lateral surfaces 246, 248.

FIG. 2B is a top-down view of the semiconductor package 104 with retreating metal layers, in accordance with various examples. FIG. 2C is a perspective view of the semiconductor package 104 with retreating metal layers, in accordance with various examples. FIG. 2D is a profile view of the semiconductor package 104 with retreating metal layers, in accordance with various examples. FIG. 2E is a bottom-up view of the semiconductor package 104 with retreating metal layers, in accordance with various examples.

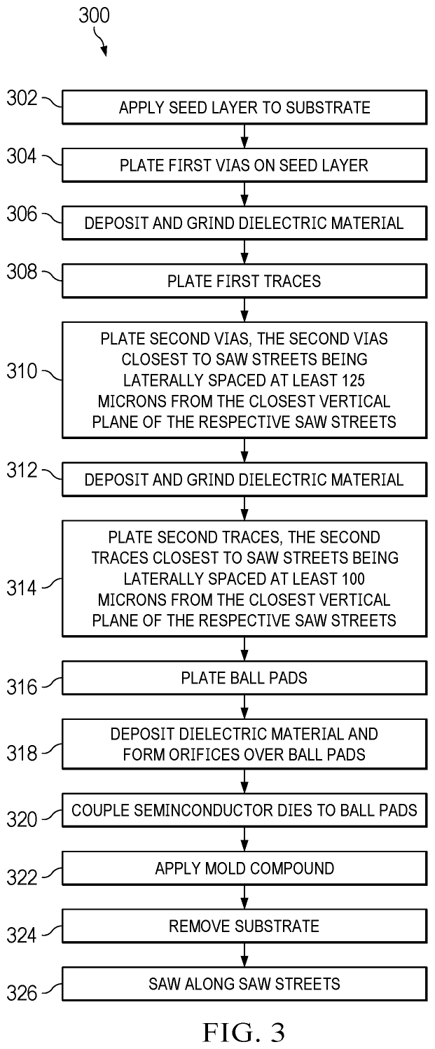

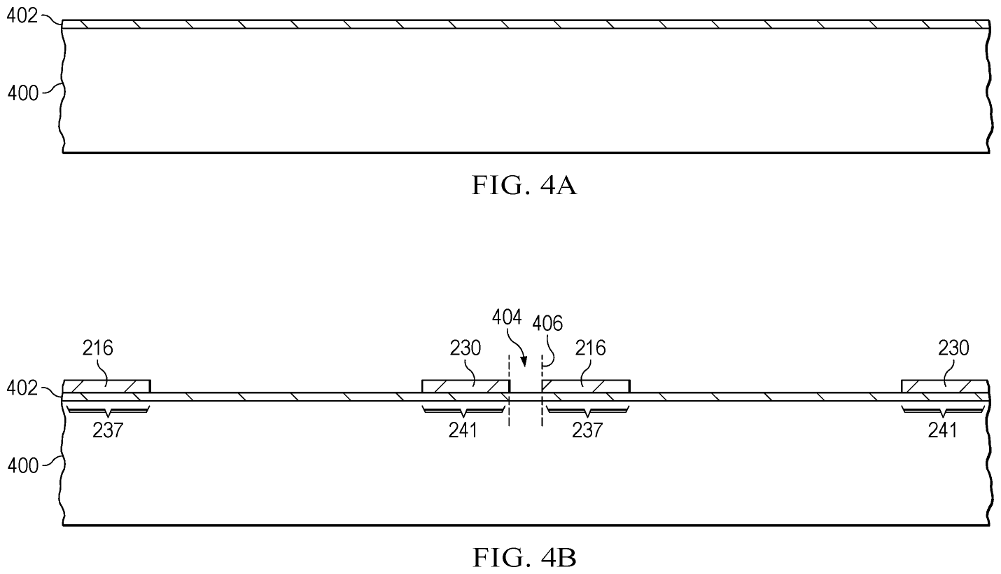

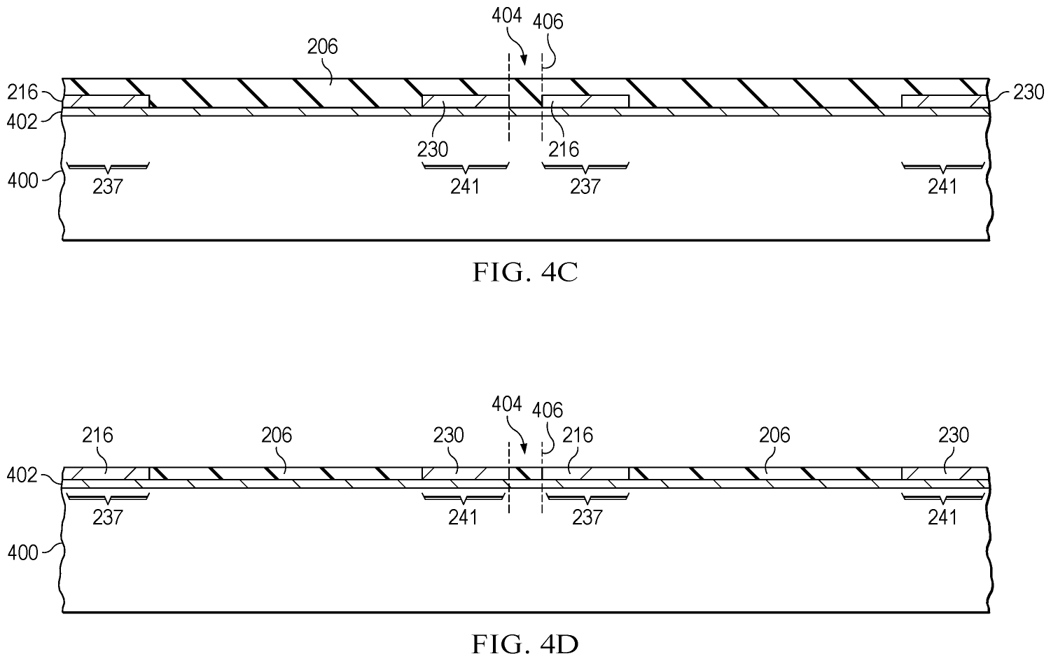

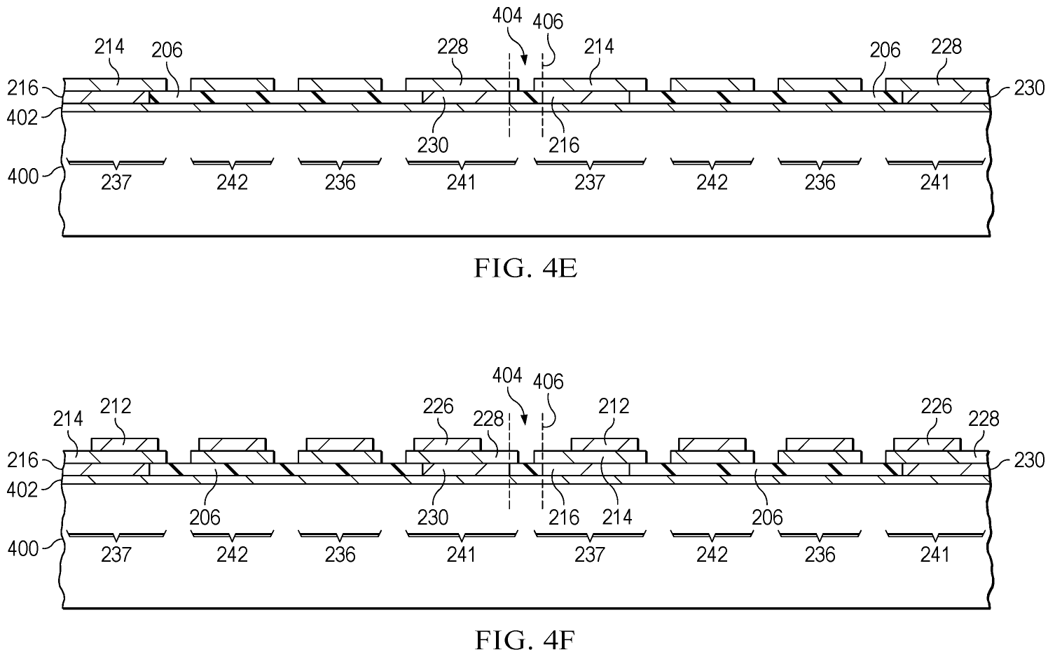

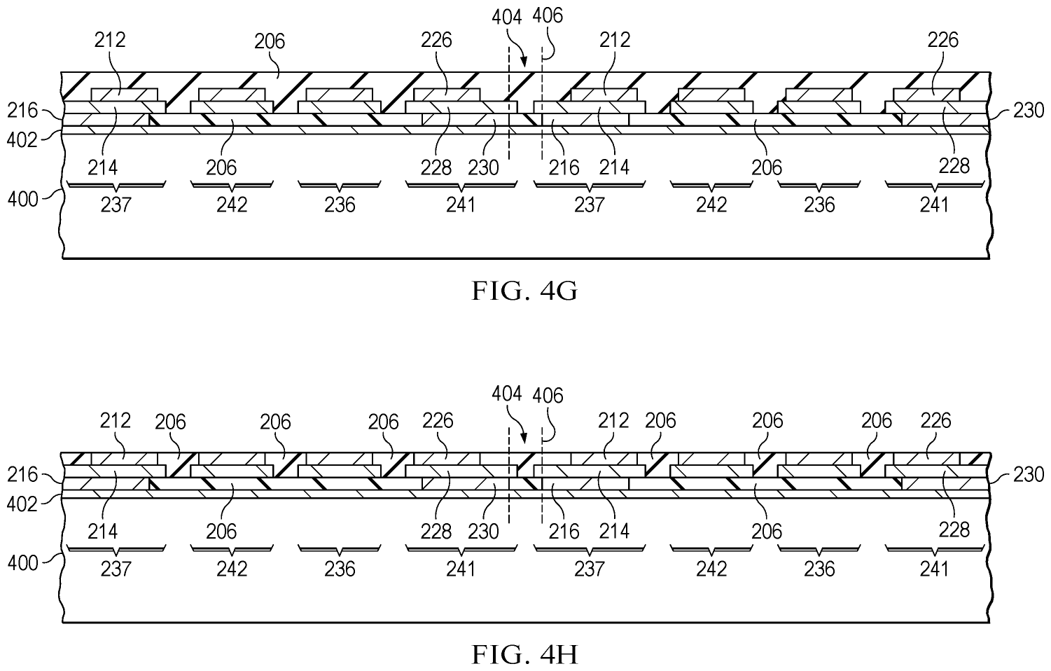

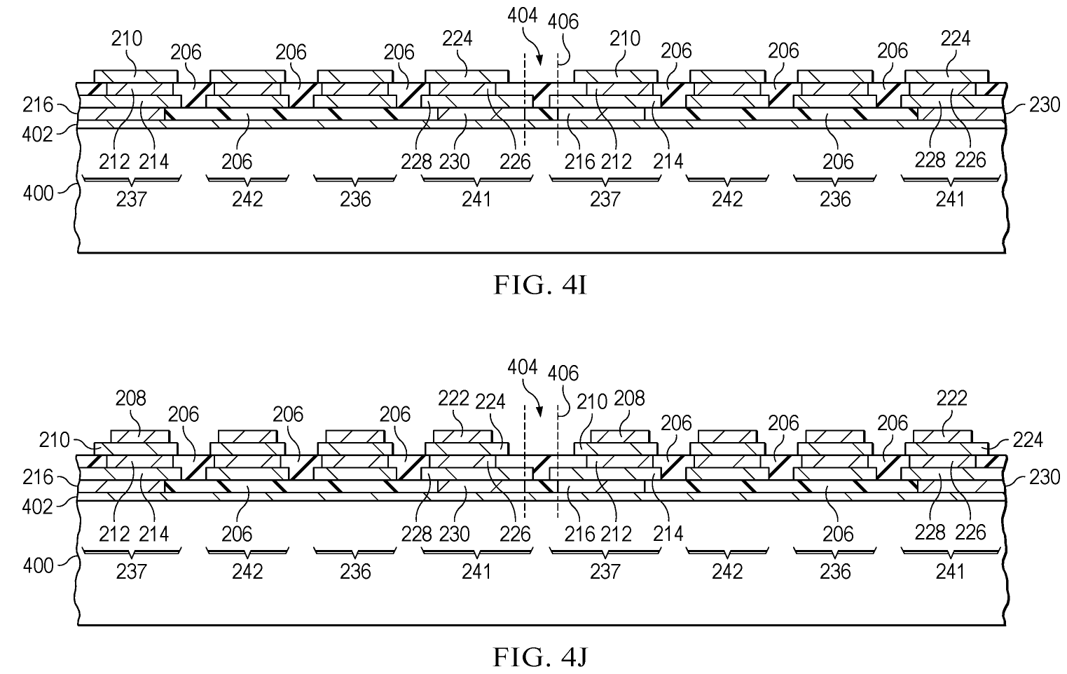

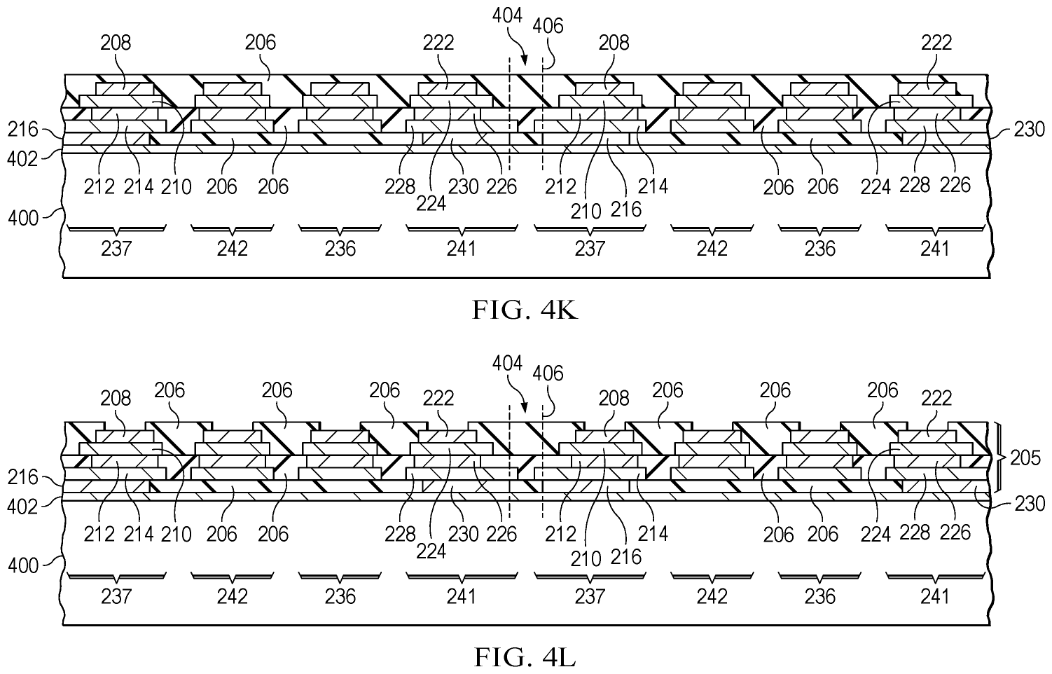

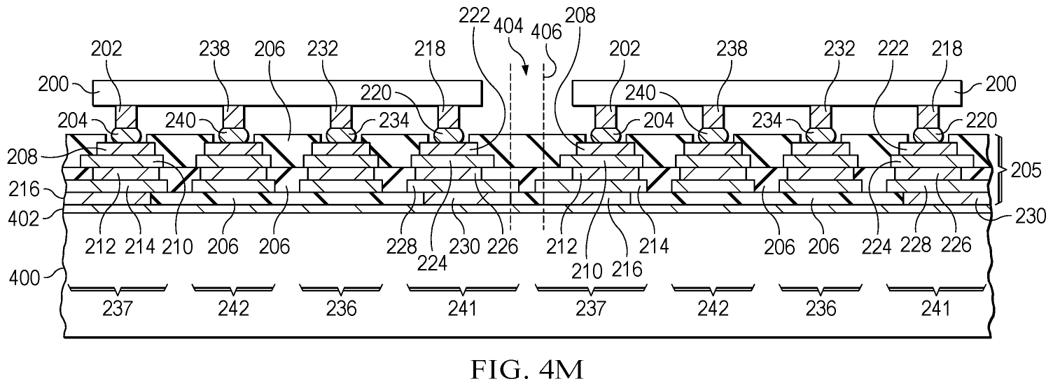

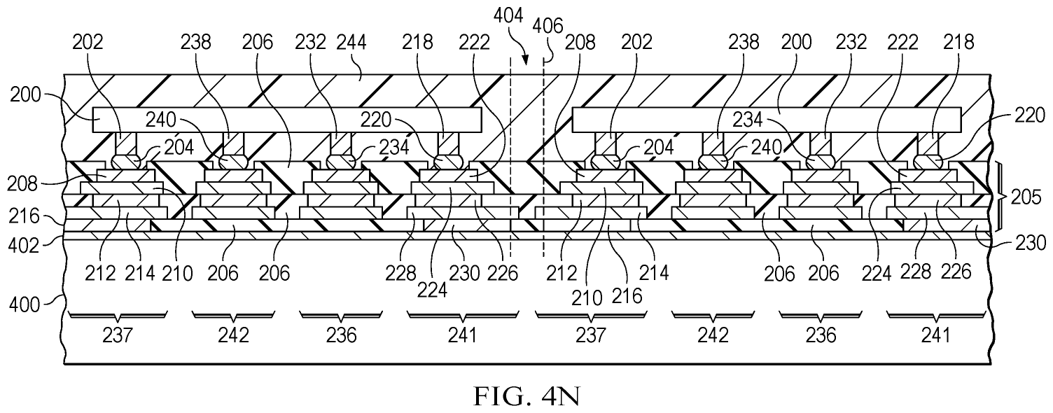

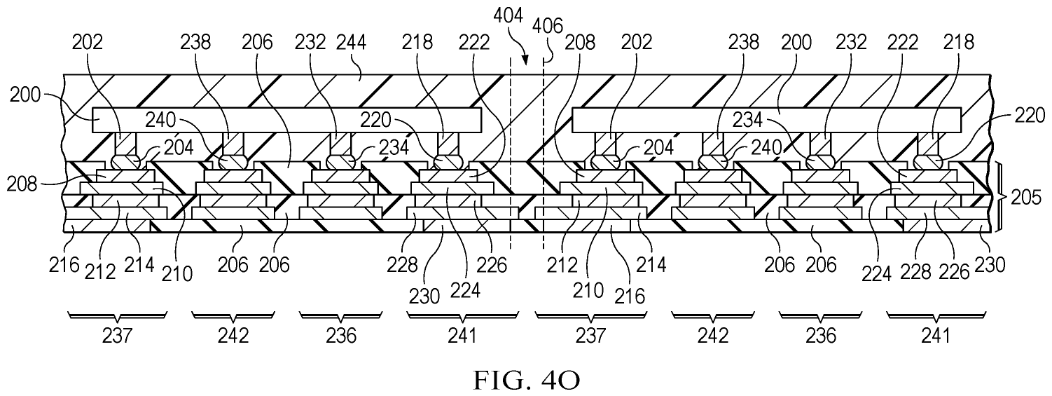

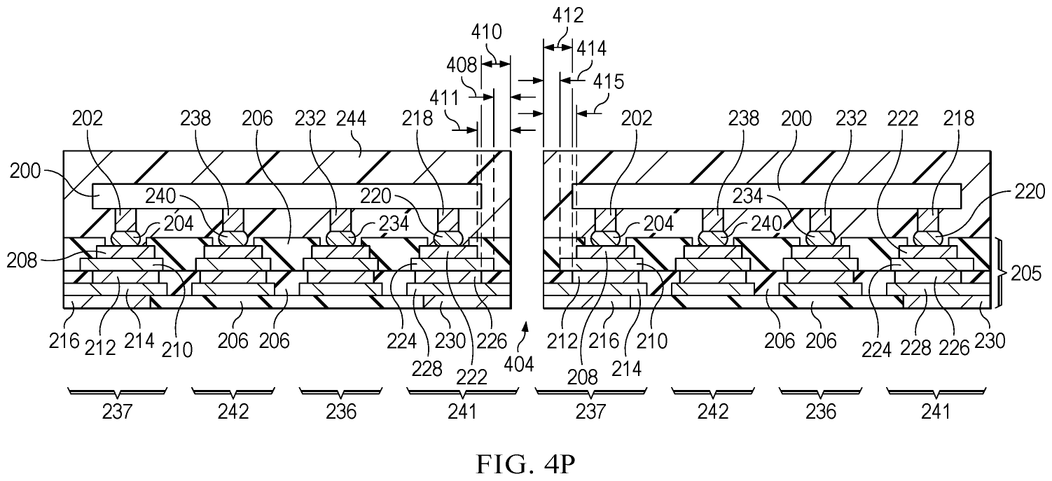

FIG. 3 is a flow diagram of a method 300 for manufacturing a semiconductor package with retreating metal layers, in accordance with various examples. FIGS. 4A-4P are a process flow for manufacturing a semiconductor package with retreating metal layers, in accordance with various examples. Accordingly, FIGS. 3 and 4A-4P are now described in parallel.

The method 300 begins by applying a seed layer to a substrate (302). FIG. 4A shows a seed layer 402 deposited (e.g., sputtered) on a substrate 400. The method 300 then includes plating first vias on the seed layer (304). FIG. 4B shows metal layers (e.g., vias) 216 and 230 plated on the seed layer 402. FIG. 4B shows two instances of metal layers 216 and two instances of metal layers 230 because the example process flow of FIGS. 4A-4P depict the manufacture of multiple (e.g., two) semiconductor packages 104. Interfaces 406 indicate the location of a saw street 404 along which a cut will subsequently be made. The location of the saw street 404 is shown throughout the process flow of FIGS. 4A-4P to demonstrate the retreat of the various metal layers as described above.

The method 300 comprises depositing and grinding dielectric material (306). FIG. 4C shows the structure of FIG. 4B, but with dielectric material 206 deposited on the metal layers 216 and 230 (e.g., by lamination). The dielectric material 206 may be deposited to be thicker than the metal layers 216 and 230, as shown. Thus, as FIG. 4D shows, a grinding process may be used to reduce the thickness of the dielectric material 206 so the top surfaces of the metal layers 216 and 230 are exposed through the top surface of the dielectric material 206, thus facilitating further plating of additional metal layers on the metal layers 216 and 230.

The method 300 then comprises plating first traces (308). FIG. 4E shows metal layers (e.g., traces) 214 and 228 plated on metal layers 216 and 230, respectively. Together, the metal layers 214 and 216 begin to form the metal stack 237, and the metal layers 228 and 230 begin to form the metal stack 241. Additional metal layers are also formed in stacks 236 and 242, as shown. Also as FIG. 4E shows, the metal layers 228 and 230 (on the left) and the metal layers 214 and 216 (on the right) interface with the saw street 404. These lower-most metal layers must interface with the saw street 404 so that, post-singulation, the metal layers may serve as conductive terminals useful to couple to the PCB 102 (e.g., by soldering). Otherwise, the semiconductor package 104 would not have an electrical pathway by which to exchange signals with the PCB 102.

The method 300 then comprises plating second vias, with the second vias closest to the saw street begin laterally spaced a distance of at least 125 microns from the closest vertical plane of the saw street (310). FIG. 4F shows the plating of metal layers (e.g., vias) 212 and 226 in stacks 237 and 241, respectively. The metal layer 226 (on the left) and the metal layer 212 (on the right) are laterally spaced at least 125 microns from their respective interfaces 406, which indicate the closest respective interfaces with the saw street 404.

The method 300 comprises depositing and grinding dielectric material (312). FIGS. 4G and 4H show the deposition of additional dielectric material 206 and the grinding of the deposited dielectric material 206, respectively. The method 300 then comprises plating second traces, with the second traces closest to the saw streets being laterally spaced at least 100 microns from the closest vertical plane of the respective saw streets (314). FIG. 41 shows the plating of metal layers (e.g., traces) 210 and 224 in metal stacks 237 and 241, respectively. Additional metal layers are also plated in metal stacks 236 and 242. The metal layers 210 and 224 are retreated from their respective interfaces 406 of the saw street 404 by at least 100 microns.

The method 300 includes plating ball pads (316), and FIG. 4J depicts the plating of metal layers (e.g., ball pads) 208 and 222 in metal stacks 237 and 241, respectively. Additional metal layers are also plated in metal stacks 236 and 242. The metal layers 208 and 222 are retreated from their respective interfaces 406 of the saw street 404 by at least 125 microns. Additional metal layers are also plated in metal stacks 236 and 242.

The method 300 includes depositing dielectric material and forming orifices over the ball pads (318). FIG. 4K shows the deposition of additional dielectric material 206, and FIG. 4L shows the formation of orifices in the top surface of the dielectric material 206, directly above the top-most metal layers in each of the metal stacks 236, 237, 241, and 242.

The method 300 comprises coupling semiconductor dies to ball pads (320). FIG. 4M shows semiconductor dies 200 being coupled to the top-most metal layers of the metal stacks 236, 237, 241, and 242 by way of conductive members 202, 238, 232, and 218, respectively, and solder bumps 204, 240, 234, and 220, respectively.

The method 300 includes applying a mold compound (322). FIG. 4N shows the application of a mold compound 244. The method 300 includes removal of a substrate (324). FIG. 4O shows the substrate 400 having been removed.

The method 300 includes sawing along the saw streets (324). FIG. 4P indicates a saw cut in saw street 404. An appropriate sawing tool (e.g., mechanical saw or laser) is selected so the cut occurs along interfaces 406. The metal layers 226, 224, and 222 are laterally offset away from the closest interface 406 of the saw street 404 by distances 410, 408, and 411, respectively, each of which is at least 100 microns, and in the case of distances 410 and 411, at least 125 microns. As explained, these minimum distances are critical to achieve the benefits of the metal layer retreats described herein. Similarly, the metal layers 212, 210, and 208 are laterally offset away from the closest interface 406 of the saw street 404 by distances 412, 414, and 415, respectively, each of which is at least 100 microns, and in the case of distances 412 and 415, at least 125 microns. As explained, these minimum distances are critical to achieve the benefits of the metal layer retreats described herein. In some examples, the distance 410 is greater than distance 408, and the distance 412 is greater than distance 414. Because the saw tool does not cut through metal layers 222, 224, or 226 (on the left side) or metal layers 208, 210, or 212 (on the right side), the stresses that would otherwise have been imparted to the structure of FIG. 4P are mitigated, as are the consequences of such stresses. For example, the interface between the dielectric material 206 and the mold compound 244 may be entirely devoid of delamination.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A semiconductor package, comprising:
a semiconductor die having a device side including circuitry formed therein;
a substrate facing and coupled to the device side, the substrate including:
first and second metal layers, the first metal layer positioned closer to the device side than the second metal layer and coupled to the second metal layer by way of a via; and
a dielectric contacting at least part of the first and second metal layers and the via; and
a mold compound covering the semiconductor die and the substrate,
wherein the package includes a lateral surface approximately perpendicular to the first and second metal layers of the substrate, and wherein the mold compound, the dielectric, and the second metal layer are exposed to the lateral surface, a segment of the dielectric positioned between the first metal layer and the lateral surface, the segment of the dielectric contacting the mold compound at the lateral surface.

2. The semiconductor package of claim 1, wherein a distance between the first metal layer and the lateral surface is at least 100 microns.

3. The semiconductor package of claim 1, wherein the dielectric includes AJINOMOTO® Build-up Film (ABF).

4. The semiconductor package of claim 1, wherein a second segment of the dielectric is positioned between the via and the lateral surface.

5. The semiconductor package of claim 4, wherein a distance between the via and the lateral surface is at least 125 microns.

6. The semiconductor package of claim 1, wherein a distance between the first metal layer and the lateral surface is smaller than a distance between the via and the lateral surface.

7. The semiconductor package of claim 1, wherein an entire boundary between the mold compound and the dielectric lacks delamination.

8. The semiconductor package of claim 1, wherein a conductive component between the second metal layer and a bottom surface of the substrate is exposed to the lateral surface.

9. A semiconductor package, comprising:
a semiconductor die having a device side including circuitry formed therein;
a substrate facing and coupled to the device side, the substrate including:
a stack of at least three metal layers having vias positioned therebetween, a first metal layer of the stack closer to the device side than a second metal layer of the stack, the second metal layer closer to the device side than a third metal layer of the stack; and
a dielectric contacting at least part of the at least three metal layers and the via; and
a mold compound covering the semiconductor die and the substrate,
wherein the package includes a lateral surface approximately perpendicular to the first metal layer, wherein the first and second metal layers are offset from the lateral surface by at least 100 microns, and wherein the dielectric contacts the mold compound at the lateral surface.

10. The semiconductor package of claim 9, wherein the dielectric includes AJINOMOTO® Build-up Film (ABF).

11. The semiconductor package of claim 9, wherein a first segment of the dielectric is positioned between the first metal layer and the lateral surface.

12. The semiconductor package of claim 11, wherein a second segment of the dielectric is positioned between one of the vias and the lateral surface.

13. The semiconductor package of claim 12, wherein a distance between the one of the vias and the lateral surface is at least 125 microns.

14. The semiconductor package of claim 12, wherein a distance between the first metal layer and the lateral surface is smaller than a distance between the via and the lateral surface.

15. The semiconductor package of claim 9, wherein an entire boundary between the mold compound and the dielectric lacks delamination.

16. The semiconductor package of claim 9, wherein the third metal layer is exposed to the lateral surface.

17. The semiconductor package of claim 16, wherein a conductive component between the third metal layer and a bottom surface of the substrate is exposed to the lateral surface.

18. A method for manufacturing a semiconductor package, comprising:
plating a first metal layer;
plating a second metal layer, a lateral end of the second metal layer displaced from a saw street closest to the lateral end by a distance of at least 100 microns;
laminating a dielectric material contacting the first and second metal layers;
coupling a device side of a semiconductor die to the second metal layer, the device side having circuitry formed therein;
covering the semiconductor die with a mold compound, the mold compound contacting the dielectric material at the saw street; and
sawing along the saw street so as to saw through the mold compound, the dielectric material, and the first metal layer, but not through the second metal layer.

19. The method of claim 18, wherein the dielectric material is AJINOMOTO® Build-Up Film (ABF).

20. The method of claim 18, wherein the sawing along the saw street does not produce delamination between the mold compound and the dielectric material.
